(19) United States
(12) Patent Application Publication
(10) Pub. No.: US 2025/0062252 A1
(43) Pub. Date: Feb. 20, 2025

(54) SEMICONDUCTOR PACKAGE

(71) Applicant: SAMSUNG ELECTRONICS CO., LTD., SUWON-SI (KR)

(72) Inventors: Jaeean Lee, Suwon-si (KR); Dongwon Kang, Suwon-si (KR); Changyeon Song, Suwon-si (KR); Sunguk Lee, Suwon-si (KR)

(21) Appl. No.: 18/742,833

(22) Filed: Jun. 13, 2024

(30) Foreign Application Priority Data
Aug. 18, 2023 (KR) 10-2023-0108544

(51) Int. Cl. H01L 23/58; H01L 23/00; H01L 23/31; H01L 23/498

(52) U.S. Cl. CPC H01L 23/585; H01L 23/3107; H01L 23/49827; H01L 24/24; H01L 24/25; H01L 23/49816; H01L 2224/2401; H01L 2224/244; H01L 2224/25171; H01L 2224/2518; H01L 2924/15174

(57) ABSTRACT

A semiconductor package includes a redistribution insulation layer and a connection structure disposed on the redistribution insulation layer in a first direction and including a base layer, a metal pattern, and a cavity. A semiconductor chip is disposed on the redistribution insulation layer in the first direction. The semiconductor chip is spaced apart from the connection structure by a molding layer. The semiconductor chip and the molding layer are disposed in the cavity. The metal pattern is disposed on the redistribution insulation layer, at least partially between the base layer and the molding layer. The metal pattern includes a first metal pattern extending, in a second direction crossing the first direction, from an inner surface of the connection structure into the base layer and separating at least a portion of the base layer from at least a portion of the redistribution insulation layer.

### CROSS-REFERENCE TO RELATED APPLICATIONS

This application claims priority under 35 U.S.C. § 119 to Korean Patent Application No. 10-2023-0108544, filed on Aug. 18, 2023, in the Korean Intellectual Property Office, the disclosure of which is incorporated by reference herein in its entirety.

### TECHNICAL FIELD

The inventive concept relates to semiconductor devices, and more particularly to a semiconductor package.

### DISCUSSION OF RELATED ART

A semiconductor is a material that has an electrical conductivity value falling between that of a conductor and an insulator. A semiconductor device is an electronic component (such as a semiconductor chip) that uses electronic properties of a semiconductor material for its function. A semiconductor package is a package including one or more semiconductor devices.

A performance of a semiconductor package may be increased by increasing an amount of external connection terminals of the semiconductor package. However, increasing the number of the external connection terminals may increase a planar area of the semiconductor package, and a manufacturing cost of the semiconductor package may concurrently increase as the planar area of the semiconductor package and the semiconductor chip increases. A fan-out package is a semiconductor package in which a semiconductor chip is connected to an external connection terminal via a connection structure having a greater planar area than that of the semiconductor chip. A fan-out package may therefore package a semiconductor chip having a reduced size while securing a sufficient planar area for an increased number of external connection terminals.

### SUMMARY

The inventive concept provides a semiconductor package having an increased structural reliability.

According to an embodiment of the inventive concept, a semiconductor package includes a redistribution insulation layer and a connection structure disposed on the redistribution insulation layer in a first direction and including a base layer, a metal pattern, and a cavity. The semiconductor package further includes a semiconductor chip disposed on the redistribution insulation layer in the first direction. The semiconductor chip is spaced apart from the connection structure. The semiconductor package further includes a molding layer disposed between the connection structure and the semiconductor chip. The semiconductor chip and the molding layer are disposed in the cavity. The metal pattern is disposed on the redistribution insulation layer in the first direction and at least partially between the base layer and the molding layer. The metal pattern includes a first metal pattern extending, in a second direction crossing the first direction, from an inner surface of the connection structure into the base layer and separating at least a portion of the base layer from at least a portion of the redistribution insulation layer.

According to an embodiment of the inventive concept, a semiconductor package includes a redistribution insulation layer and a connection structure disposed on the redistribution insulation layer in a first direction. The connection structure includes a base layer, a metal pattern, and a cavity. The semiconductor package further includes a semiconductor chip disposed on the redistribution insulation layer in the first direction. The semiconductor chip is spaced apart from the connection structure. The semiconductor package further includes a molding layer disposed between the connection structure and the semiconductor chip. The semiconductor chip and the molding layer are disposed in the cavity. The metal pattern is disposed on the redistribution insulation layer in the first direction and at least partially between the base layer and the molding layer. The metal pattern includes a first metal pattern extending, in a second direction crossing the first direction, from an inner surface of the connection structure into the base layer and separating at least a portion of the base layer from at least a portion of the redistribution insulation layer. The metal pattern further includes a second metal pattern disposed on an inner surface of the first metal pattern and extending in the first direction. The metal pattern further includes a third metal pattern disposed on a top surface in the first direction of the second metal pattern and extending, in the second direction, from an inner surface of the second metal pattern toward the connection structure.

According to an embodiment of the inventive concept, a semiconductor package includes a first redistribution structure including a plurality of first redistribution line patterns and a first redistribution insulation layer at least partially surrounding the plurality of first redistribution line patterns. The semiconductor package further includes a connection structure disposed on the first redistribution structure in a first direction and including a metal pattern, a cavity, a plurality of connection pads, a plurality of connection vias, and a plurality of base layers at least partially surrounding the plurality of connection vias. Connection pads of the plurality of connection pads are disposed on different levels in the first direction from each other. The plurality of connection vias interconnect the plurality of connection pads. The semiconductor package further includes a semiconductor chip disposed on the first redistribution structure in the first direction and a molding layer disposed between the connection structure and the semiconductor chip and covering a top surface in the first direction of the connection structure and of the semiconductor chip. The semiconductor chip and the molding layer are disposed in the cavity. The semiconductor package further includes a second redistribution structure disposed on the semiconductor chip in the first direction and including a plurality of second redistribution line patterns and a second redistribution insulation layer at least partially surrounding the plurality of second redistribution line patterns. The metal pattern is at least partially disposed between the plurality of base layers and the molding layer. The metal pattern includes a first metal pattern extending, in a second direction crossing the first direction, from an inner surface of the connection structure into the plurality of base layers and separating at least a portion of the plurality of base layers from at least a portion of the first redistribution structure. The metal pattern further includes a second metal pattern disposed on an inner surface of the first metal pattern and extending in the first direction from a top surface in the first direction of the first redistribution structure to a top surface in the first direction of an uppermost base layer in the first direction of the plurality of base layers. The metal pattern further includes a third metal pattern disposed on a top surface in the first direction of the second metal pattern and of the uppermost base layer and extending, in the second direction, from an inner surface of the second metal pattern toward the plurality of base layers.

### BRIEF DESCRIPTION OF THE DRAWINGS

The above and other features of the inventive concept will become more apparent by describing in detail embodiments thereof with reference to the accompanying drawings, in which:

FIG. 1 is a cross-sectional view of a semiconductor package according to an embodiment of the inventive concept;

FIG. 2 is an enlarged cross-sectional view of a portion EX1 of FIG. 1 according to an embodiment of the inventive concept;

FIG. 3 is a cross-sectional view of a semiconductor package according to an embodiment of the inventive concept;

FIG. 4 is an enlarged cross-sectional view of a portion EX2 of FIG. 3 according to an embodiment of the inventive concept;

FIG. 5 is a cross-sectional view of a semiconductor package according to an embodiment of the inventive concept;

FIG. 6 is an enlarged cross-sectional view of a portion EX3 of FIG. 5 according to an embodiment of the inventive concept; and

FIGS. 7 to 20 are cross-sectional views for describing a method of manufacturing a semiconductor package according to an embodiment of the inventive concept.

### DETAILED DESCRIPTION OF THE EMBODIMENTS

Embodiments of the inventive concept will be described more fully hereinafter with reference to the accompanying drawings. Like numerals may refer to like elements throughout. As used herein, the singular forms, “a”, “an” and “the” are intended to include the plural forms as well, unless the context clearly indicates otherwise.

It will be understood that, although the terms “first”, “second”, etc. may be used herein to describe various elements, these elements should not be limited by these terms. These terms are only used to distinguish one element from another element. Thus, a first element discussed below could be termed a second element without departing from the teachings of the inventive concept. As used herein, the term “and/or” includes any and all combinations of one or more of the associated listed items.

According to some aspects, a semiconductor package includes a metal pattern and a semiconductor chip disposed on a redistribution insulation layer of a redistribution structure, in and/or adjacent to a cavity of a connection structure of the semiconductor package. In some embodiments, at least a portion of the metal pattern is disposed between a base layer of the connection structure and the redistribution insulation layer. In some embodiments, the metal pattern therefore prevents contact between the portion of the base layer and the portion of the redistribution insulation layer, such that a potential defect in the base layer may be prevented from causing a potential defect in the redistribution insulation layer during a formation process. Accordingly, in some embodiments, a structural reliability of the semiconductor package is increased.

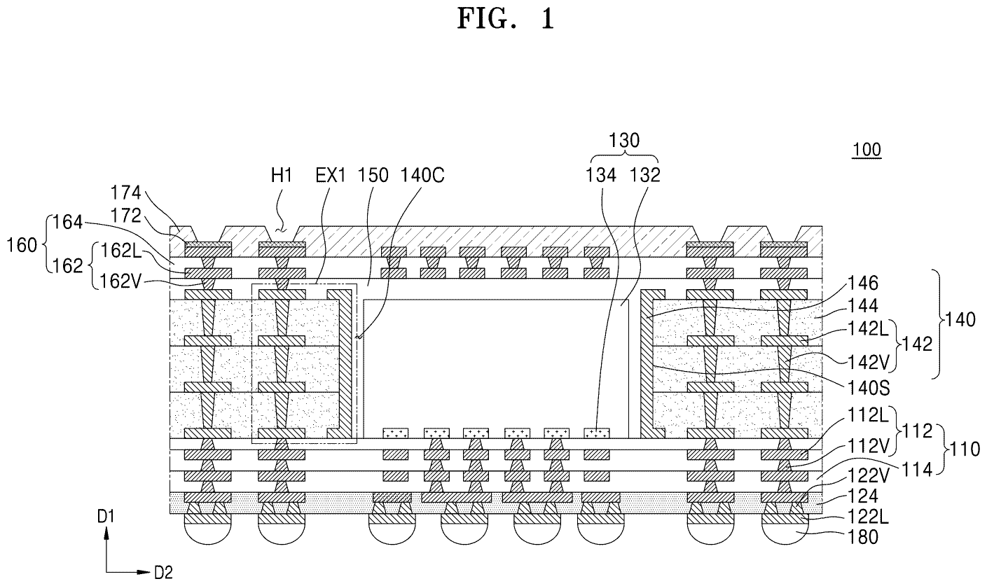

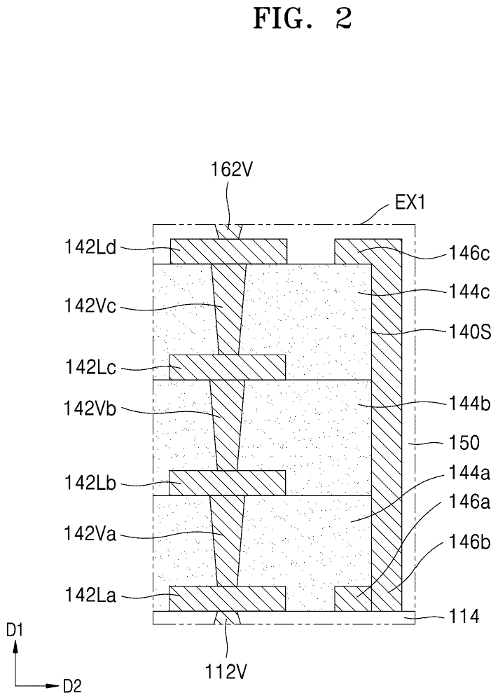

FIG. 1 is a cross-sectional view of a semiconductor package 100 according to an embodiment of the inventive concept. FIG. 2 is an enlarged cross-sectional view of a portion EX1 of FIG. 1 according to an embodiment of the inventive concept.

Referring to FIGS. 1 and 2, according to some aspects, the semiconductor package 100 includes a first redistribution structure 110, a semiconductor chip 130 disposed on the first redistribution structure 110, and a connection structure 140 having a cavity 140C. In some embodiments, the semiconductor chip 130 is disposed on the first redistribution structure 110 in a first direction D1 (e.g., a vertical direction).

According to some aspects, the first redistribution structure 110 includes a plurality of first redistribution patterns 112 and a plurality of first redistribution insulation layers 114. In some embodiments, one or more first redistribution patterns of the plurality of first redistribution patterns 112 are stacked on each other in the first direction D1. In some embodiments, one or more first redistribution insulation layers of the first redistribution insulation layers 114 are stacked on each other in the first direction D1.

According to some aspects, a first redistribution insulation layer 114 at least partially covers a first redistribution pattern 112. In some embodiments, a first redistribution insulation layer 114 at least partially covers one or more first redistribution patterns 112 disposed on a same level in the first direction D1 as each other. In some embodiments, a first redistribution insulation layer 114 includes a photoimageable dielectric (PID) material, an Ajinomoto Build-up Film® material, a solder resist (SR) material (e.g., a solder mask material), an epoxy molding compound (EMC) material, a flame retardant 4 (FR-4) material, or a Bismaleimide Triazine (BT) material. For example, in some embodiments, a first redistribution insulation layer 114 includes a PID material layer.

According to some aspects, the first redistribution structure 110 includes a plurality of first redistribution line patterns 112L. In some embodiments, the first redistribution structure 110 includes a plurality of first redistribution via patterns 112V. In some embodiments, a first redistribution pattern 112 includes a first redistribution line pattern 112L and a first redistribution via pattern 112V. In some embodiments, a first redistribution pattern 112 includes a first redistribution line pattern 112L disposed on a first redistribution via pattern 112V in the first direction. In some embodiments, a “line pattern” refers to a line. In some embodiments, a “via pattern” refers to a via.

According to some aspects, one or more first redistribution line patterns 112L extend within a first redistribution insulation layer 114 in a second direction D2 crossing the first direction D1 (e.g., a horizontal direction) parallel to a top surface in the first direction D1 of the first redistribution insulation layer 114. In some embodiments, a first redistribution line pattern 112L is located at a vertical level different from a vertical level at which another first redistribution line pattern 112L is located. For example, in some embodiments, a first redistribution line pattern 112L is disposed on a different level in the first direction D1 than another redistribution line pattern 112L.

According to some aspects, one or more first redistribution via patterns 112V extend within a first redistribution insulation layer 114 in the first direction D1 (e.g., the vertical direction) perpendicular to a top surface in the first direction D1 of the first redistribution insulation layer 114. According to some aspects, one or more first redistribution via patterns 112V extend within a first redistribution insulation layer 114 in the second direction D2 parallel to a top surface in the first direction D1 of the first redistribution insulation layer 114. In some embodiments, a first redistribution via pattern 112V is disposed on a different level in the first direction D1 than another redistribution via pattern 112V.

In some embodiments, an uppermost first redistribution insulation layer in the first direction D1 is disposed at a same level in the first direction D1 as one or more first redistribution via patterns 112V and is not disposed at a same level in the first direction D1 as a first redistribution line pattern 112L. In some embodiments, an uppermost first redistribution insulation layer in the first direction D1 surrounds two sides of a first redistribution via pattern 112V and does not surround two sides of a first redistribution line pattern 112L.

According to some aspects, the plurality of first redistribution via patterns 112V interconnect the plurality of first redistribution line patterns 112L located at different vertical levels. For example, in some embodiments, a first redistribution via pattern 112V connects a pair of redistribution line patterns 112L disposed on different levels in the first direction D1 from each other.

According to some aspects, the plurality of first redistribution via patterns 112V interconnect at least some uppermost first redistribution line patterns 112L in the first direction D1 from among the plurality of first redistribution line patterns 112L and at least some chip pads 134 of a plurality of chip pads 134 of the semiconductor chip 130. For example, in some embodiments, a first redistribution via pattern 112V connects a first redistribution line pattern 112L and a chip pad 134.

According to some aspects, the plurality of first redistribution via patterns 112V interconnect at least some uppermost first redistribution line patterns 112L in the first direction D1 from among the plurality of first redistribution line patterns 112L and at least some first connection pads 142La from among a plurality of connection pads 142L of the connection structure 140. For example, in some embodiments, a first redistribution via pattern 112V connects a first redistribution line pattern 112L and a first connection pad 142La.

According to some aspects, one or more first redistribution via patterns 112V have a tapered shape such that a horizontal width (e.g., a width in the second direction D2) of the first redistribution via pattern 112V increases in a direction away from a bottom surface of the semiconductor chip 130 (e.g., a bottom surface in the first direction D1). For example, in some embodiments, a higher portion in the first direction D1 of a first redistribution via pattern 112V is narrower in the second direction D2 than a lower portion in the first direction D1 of the first redistribution via pattern 112V.

According to some aspects, the first redistribution pattern 112 includes copper (Cu), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

According to some aspects, a plurality of conductive pads 122L and a plurality of conductive via patterns 122V are arranged or disposed on a bottom surface in the first direction D1 of the first redistribution structure 110. In some embodiments, the plurality of conductive via patterns 122V contact lowermost first redistribution line patterns 112L in the first direction D1 from among the plurality of first redistribution line patterns 112L. In some embodiments, a pair of conductive via patterns 122V contact a lowermost first redistribution line pattern 112L.

According to some aspects, the plurality of conductive via patterns 122V are at least partially surrounded by a lower insulation layer 124. In some embodiments, the lower insulation layer 124 comprises an insulating material. In some embodiments, the lower insulation layer includes a photoimageable dielectric (PID) material, an Ajinomoto Build-up Film® material, a solder resist (SR) material (e.g., a solder mask material), an epoxy molding compound (EMC) material, a flame retardant 4 (FR-4) material, or a Bismaleimide Triazine (BT) material. For example, in some embodiments, the lower insulation layer 124 includes a PID material layer. In some embodiments, the plurality of conductive pads 122L are respectively arranged or disposed on bottom surfaces in the first direction D1 of the plurality of conductive via patterns 122V. In some embodiments, a pair of conductive via patterns 122V contact a conductive pad 122L. In some embodiments, the plurality of conductive pads 122L are respectively connected to the lowermost first redistribution line patterns 112L through the plurality of conductive via patterns 122V.

According to some aspects, one or more conductive via patterns 122V have a tapered shape. For example, in some embodiments, a higher portion in the first direction D1 of a conductive via pattern 122V is narrower in the second direction D2 than a lower portion in the first direction D1 of the conductive via pattern 122V.

In some embodiments, a pair of conductive via patterns 122V connect a lowermost first redistribution line pattern 112L and a conductive pad 122L. In some embodiments, one or more conductive pads 122L and one or more conductive via patterns 122V each include an under-bump metallurgy (UBM) layer including nickel (Ni), titanium (Ti), titanium tungsten (TiW), gold (Au), aluminum (Al), nickel-vanadium (NiV), chromium (Cr), copper (Cu), or a combination thereof.

According to some aspects, a plurality of external connection terminals 180 are arranged or disposed on the plurality of conductive pads 122L. In some embodiments, each external connection terminal 180 respectively contacts one conductive pad 122L. In some embodiments, an external connection terminal 180 does not contact more than one conductive pad 122L. In some embodiments, one or more external connection terminals 180 include tin (Sn), silver (Ag), copper (Cu), nickel (Ni), or a combination thereof. In some embodiments, an external connection terminal 180 includes a solder ball.

According to some aspects, a semiconductor chip 130 is disposed on a top surface in the first direction D1 of the first redistribution structure 110. In some embodiments, a semiconductor chip 130 includes a logic chip or a memory chip. In some embodiments, the logic chip comprises a microprocessor. For example, in some embodiments, the logic chip comprises a central processing unit (CPU), a controller, an application specific integrated circuit (ASIC), etc. In some embodiments, the memory chip comprises a volatile memory chip, such as dynamic random access memory (DRAM) or static random access memory (SRAM), or a non-volatile memory chip, such as phase-change random access memory (PRAM), magneto-resistive random access memory (MRAM), ferroelectric random access memory (FeRAM), or resistive random access memory (RRAM).

According to some aspects, the semiconductor package 100 includes one semiconductor chip 130. In some embodiments, the semiconductor package 100 includes two or more semiconductor chips 130.

According to some aspects, a semiconductor chip 130 includes a semiconductor substrate 132 and a plurality of chip pads 134. In some embodiments, the semiconductor substrate 132 includes silicon (Si). In some embodiments, the semiconductor substrate 132 includes a semiconductor element, such as germanium (Ge), or a compound semiconductor, such as silicon carbide (SiC), gallium arsenide (GaAs), indium arsenide (InAs), or indium phosphide (InP).

According to some aspects, the semiconductor substrate 132 includes an active surface and an inactive surface facing the active surface. For example, in some embodiments, the active surface is a bottom surface in the first direction D1 of the semiconductor substrate 132 on which the plurality of chip pads 134 are arranged or disposed, and the inactive surface is a top surface in the first direction D1 of the semiconductor substrate 132 facing the bottom surface of the semiconductor substrate 132.

According to some aspects, the active surface of the semiconductor substrate 132 includes a plurality of individual devices of various types. For example, in some embodiments, the individual devices may include various microelectronic devices such as a complementary metal-oxide semiconductor (CMOS) transistor, a metal-oxide-semiconductor field effect transistor (MOSFET), a system large scale integration (LSI), an image sensor like a CMOS imaging sensor (CIS), a micro-electro-mechanical system (MEMS), an active device, a passive device, etc.

In some embodiments, the plurality of chip pads 134 are arranged or disposed on the bottom surface of the semiconductor substrate 132. In some embodiments, the plurality of chip pads 134 are electrically connected to a plurality of individual devices of various types included in the active surface. In some embodiments, the chip pads 134 are electrically connected to at least some uppermost first redistribution via patterns 112V in the first direction D1 from among the plurality of first redistribution via patterns 112V of the first redistribution structure 110.

According to some aspects, the connection structure 140 is disposed on the first redistribution structure 110. In some embodiments, the connection structure 140 includes a cavity 140C in a center region of the connection structure 140. In some embodiments, the cavity 140C provides a space for the semiconductor chip 130 to be disposed. For example, in some embodiments, the semiconductor chip 130 is disposed in the cavity 140C.

According to some aspects, the connection structure 140 horizontally surrounds the semiconductor chip 130. For example, in some cases, the semiconductor chip 130 extends from a first side to a second side in the second direction D2, and the connection structure 140 surrounds both the first side and the second side. In some embodiments, inner surfaces 140S of the connection structure 140 are horizontally spaced apart from side surfaces of the semiconductor chip 130. For example, in some embodiments, a side of the semiconductor chip 130 extending in the first direction D1 is spaced apart in the second direction D2 from a side of the connection structure 140 extending in the first direction D1 (e.g., the inner surface 140S). In some cases, the inner surface 140S is a surface facing the cavity 140C and/or the semiconductor chip 130.

In some embodiments, because the semiconductor package 100 includes the connection structure 140, the semiconductor package 100 comprises a fan-out panel level package (FOPLP). In some embodiments, the connection structure 140 comprises a printed circuit board (PCB), a ceramic substrate, a wafer for package manufacturing, or an interposer. For example, in some embodiments, the connection structure 140 comprises a multi-layer PCB.

According to some aspects, the connection structure 140 includes a plurality of base layers 144 and a plurality of via structures 142. Referring to FIG. 2, in some embodiments, the plurality of base layers 144 includes a first base layer 144a, a second base layer 144b, and a third base layer 144c. In some embodiments, the plurality of base layers 144 are stacked in a vertical direction (e.g., the first direction D1). For example, in some embodiments, the plurality of base layers 144 comprises a multi-layer substrate including the first base layer 144a, the second base layer 144b, and the third base layer 144c. In some embodiments, the plurality of base layers 144 at least partially surrounds at least some via structures 142 of a plurality of via structures 142.

According to some aspects, one or more base layers 144 include a thermosetting resin, such as a phenol resin or an epoxy resin, a thermoplastic resin, such as a polyimide, or an insulation material formed by impregnating at least one resin selected from among a thermosetting resin and a thermoplastic resin in a core material including an inorganic filler and/or glass fiber. For example, in some embodiments, one or more base layers 144 include prepreg, Ajinomoto Build-up Film®, flame retardant 4 (FR-4), tetrafunctional epoxy, polyphenylene ether, Bismaleimide Triazine (BT), epoxy/polyphenylene oxide, Thermount®, cyanate ester, polyimide, liquid crystal polymer, or a combination thereof. For example, in some embodiments, one or more of a first base layer 144a, a second base layer 144b, and a third base layer 144c each include prepreg. In some embodiments, one or more base layers 144 include an epoxy-based material, a thermosetting material, or a thermoplastic material.

According to some aspects, the connection structure 140 includes a plurality of via structures 142. In some embodiments, the connection structure 140 includes a plurality of connection pads 142L. In some embodiments, the connection structure 140 includes a plurality of connection via patterns 142V. In some embodiments, a via structure 142 includes a connection pad 142L and a connection via pattern 142V.

According to some aspects, a plurality of connection pads 142L extend in the horizontal direction (e.g., in the second direction D2) on the top surfaces and/or the bottom surfaces in the first direction D1 of the plurality of base layers 144, respectively. For example, in some embodiments, one or more connection pads 142L extend in the second direction D1 on a top surface and/or a bottom surface in the first direction D1 of a base layer 144.

Referring to FIGS. 1 and 2, according to some aspects, a plurality of connection pads 142L includes one or more first connection pads 142La, one or more second connection pads 142 Lb, one or more third connection pads 142Lc, and one or more fourth connection pads 142Ld located at different vertical levels. For example, in some embodiments, each of a first connection pad 142La, a second connection pad 142 Lb, a third connection pad 142Lc, and a fourth connection pad 142Ld are disposed on different levels in the first direction D1 from each other. In some embodiments, a first connection pad 142La is a lowermost connection pad 142L in the first direction D1 and is connected to the first redistribution structure 110. In some embodiments, a fourth connection pad 142Ld is an uppermost connection pad 142L in the first direction D1 and is connected to a second redistribution structure 160 (including, for example, a second redistribution pattern 162V). In some embodiments, at least a portion of one or more surfaces of one or more fourth connection pads 142Ld is surrounded by a molding layer 150.

According to some aspects, the plurality of connection via patterns 142V extend in the vertical direction (e.g., in the first direction D1) within the plurality of base layers 144. Referring to FIGS. 1 and 2, in some embodiments, the plurality of connection via patterns 142V includes one or more first connection via patterns 142Va, one or more second connection via patterns 142Vb, and one or more third connection via patterns 142Vc located at different vertical levels. For example, in some embodiments, each of a first connection via pattern 142Va, a second connection via pattern 142Vb, and a third connection via pattern 142Vc are disposed on different levels in the first direction D1 from each other.

According to some aspects, a plurality of connection via patterns 142V interconnect the plurality of connection pads 142L located at different vertical levels. For example, in some embodiments, a first connection via pattern 142Va interconnects a first connection pad 142La and a second connection pad 142 Lb, a second connection via pattern 142Vb interconnects the second connection pad 142 Lb and a third connection pad 142Lc, and a third connection via pattern 142Vc interconnects the third connection pad 142Lc and a fourth connection pad 142Ld.

According to some aspects, one or more connection via patterns 142V have a tapered shape. For example, in some embodiments, a higher portion in the first direction D1 of a connection via pattern 142V is wider in the second direction D2 than a lower portion in the first direction D1 of the connection via pattern 142V.

According to some aspects, one or more connection pads 142L includes an electrolytically deposited (ED) copper foil, a rolled-annealed (RA) copper foil, a stainless steel foil, an aluminum foil, an ultra-thin copper foil, sputtered copper, or a copper alloy. In some embodiments, one or more connection via patterns 142V include copper (Cu), nickel (Ni), stainless steel, beryllium copper (BeCu), or a combination thereof.

According to some aspects, the connection structure 140 includes one or more metal patterns 146. In some embodiments, a metal pattern 146 is disposed on an inner surface 140S of the connection structure 140. In some cases, the inner surface 140S is a surface of one or more base layers 144, where the inner surface 140S extends in the first direction D1 and faces away from the one or more base layers 144 and toward the semiconductor chip 130 and/or the cavity 140C. In some embodiments, a metal pattern 146 is a plurality of metal patterns. Referring to FIGS. 1 and 2, in some embodiments, a metal pattern 146 includes a first metal pattern 146a, a second metal pattern 146b, and a third metal pattern 146c.

According to some aspects, a first metal pattern 146a is disposed on the top surface of the first redistribution structure 110 in the first direction D1 and extends from the inner surface 140S of the connection structure 140 into the first base layer 144a (e.g., a lowermost base layer 144 in the first direction D1 of the plurality of base layers 144 in a horizontal direction (e.g., in the second direction D2). In some embodiments, a first metal pattern 146a is horizontally spaced apart (e.g., spaced apart in the second direction D2) from the first connection pad 142La. In some embodiments, a first base layer 144a is disposed between a first connection pad 142La and a first metal pattern 146a.

According to some aspects, in a region where the first metal pattern 146a is disposed, the first base layer 144a and the uppermost first redistribution insulation layer from among the plurality of first redistribution insulation layers 114 are spaced apart from each other in a vertical direction with the first metal pattern 146a therebetween. Accordingly, in some embodiments, in the region where the first metal pattern 146a is disposed, the first base layer 144a and the first redistribution insulation layer 114 do not contact each other.

According to some aspects, at least a portion of the first base layer 144a and at least a portion of the uppermost first redistribution insulation layer are spaced apart from each other in the first direction D1. In some embodiments, the first metal pattern 146a is disposed between at least the portion of the first base layer 144a and at least the portion of the uppermost first redistribution insulation layer. In some embodiments, at least the portion of the first base layer 144a and at least the portion of the uppermost first redistribution insulation layer do not contact each other.

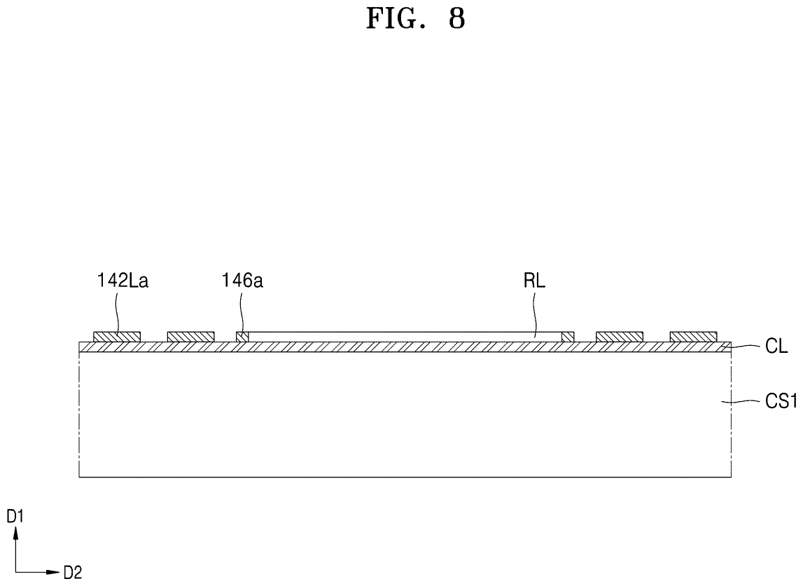

According to some aspects, a first metal pattern 146a and a first connection pad 142La are located at the same vertical level. For example, in some embodiments, a first metal pattern 146a and a first connection pad 142La are disposed on a same level in the first direction D1 as each other. According to some aspects, a length of a first metal pattern 146a in the vertical direction (e.g., in the first direction D1) is equal to a length of a first connection pad 142La in the vertical direction (e.g., in the first direction D1). In some embodiments, the respective lengths of the first metal pattern 146a and the first connection pad 142La are equal because the first metal pattern 146a and the first connection pad 142La are formed simultaneously, as described with reference to FIG. 8.

According to some aspects, a first metal pattern 146a includes a top surface in the first direction D1, extending in the second direction D2. According to some aspects, the first metal pattern 146a includes an inner surface extending in the first direction D1. According to some aspects, the first metal pattern 146a includes an outer surface extending in the first direction D1. In some embodiments, the inner surface of the first metal pattern 146a is spaced apart from the outer surface of the first metal pattern 146a in the second direction D2. In some embodiments, the outer surface of the first metal pattern 146a is further from the semiconductor chip 130 in the second direction D2 than the inner surface of the first metal pattern 146a. In some embodiments, the inner surface of the first metal pattern 146a is a surface facing away from the plurality of base layers 144 and toward the semiconductor chip 130 and/or the cavity 140C.

According to some aspects, a top surface of the first metal pattern 146a and an outer surface of the first metal pattern 146a are surrounded by the first base layer 144a. According to some aspects, an inner surface of the first metal pattern 146a contacts the second metal pattern 146b. According to some aspects, an inner surface of a first metal pattern 146a is located on (e.g., disposed on) a same plane as an inner surface 140S of the connection structure 140.

According to some aspects, a second metal pattern 146b is disposed on the inner surface relatively close to the semiconductor chip 130 from both side inner surfaces of the first metal pattern 146a. In some embodiments, a second metal pattern 146b is disposed on an inner surface of a first metal pattern 146a. In some embodiments, a second metal pattern 146b is disposed on an inner surface 140S of the connection structure 140. In some embodiments, the second metal pattern 146b extends in the vertical direction (e.g., in the first direction D1) on the inner surface of the first metal pattern 146a.

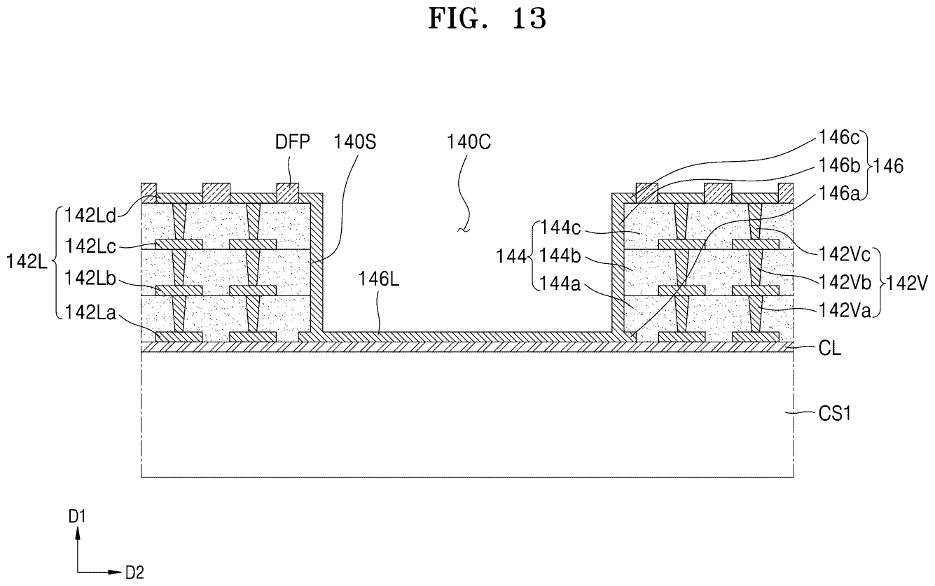

According to some aspects, a top surface in the first direction D1 of the second metal pattern 146b is located on (e.g., disposed on) a same plane as a bottom surface in the first direction D1 of a fourth connection pad 142Ld. According to some aspects, a horizontal width (e.g., a width in the second direction D2) of the second metal pattern 146b is equal to a length of the fourth connection pad 142Ld in the vertical direction (e.g., in the first direction D1). In some embodiments, the width of the second metal pattern 146b is equal to the length of the fourth connection pad 142Ld because the second metal pattern 146b and the fourth connection pad 142Ld are formed simultaneously through a same process as described with reference to FIG. 13.

According to some aspects, a second metal pattern 146b includes an inner surface extending in the first direction D1. According to some aspects, the second metal pattern 146b includes an outer surface extending in the first direction D1. In some embodiments, the inner surface of the second metal pattern 146b is spaced apart from the outer surface of the second metal pattern 146b in the second direction D2. In some embodiments, the outer surface of the second metal pattern 146b is further from the semiconductor chip 130 in the second direction D2 than the inner surface of the second metal pattern 146b. In some embodiments, the inner surface of the second metal pattern 146b is a surface facing away from the plurality of base layers 144 and toward the semiconductor chip 130 and/or the cavity 140C.

According to some aspects, a third metal pattern 146c is disposed on a top surface in the first direction D1 of a second metal pattern 146b and a top surface in the first direction D1 of a third base layer 144c. In some embodiments, the third metal pattern 146c extends from an inner surface of the second metal pattern 146b toward the plurality of base layers 144 in the horizontal direction (e.g., in the second direction D2). In some embodiments, a third metal pattern 146c is horizontally spaced apart (e.g., spaced apart in the second direction D2) from a fourth connection pad 142Ld.

According to some aspects, a third metal pattern 146c is located at a same vertical level as a fourth connection pad 142Ld. In some embodiments, a third metal pattern 146 is disposed on a same level in the first direction D1 as a fourth connection pad 142Ld. In some embodiments, a length in the vertical direction (e.g., in the first direction D1) of the third metal pattern 146c is equal to a length in the vertical direction (e.g., in the first direction D1) of a fourth connection pad 142Ld. In some embodiments, the respective lengths of the third metal pattern 146c and the fourth connection pad 142Ld are equal because the third metal pattern 146c and the fourth connection pad 142Ld are formed simultaneously through a same process as described with reference to FIG. 13.

According to some aspects, a second metal pattern 146b and a third metal pattern 146c are integrally formed as one structure. In some embodiments, a second metal pattern 146b and a third metal pattern 146c are comprised in one structure. In some embodiments, a second metal pattern 146b and a third metal pattern 146c are one structure including a same material, where a boundary between the second metal pattern 146b and the third metal pattern 146c is omitted.

According to some aspects, one or more of a first metal pattern 146a, a second metal pattern 146b, and a third metal pattern 146c include an ED copper foil, an RA copper foil, a stainless steel foil, an aluminum foil, an ultra-thin copper foil, sputtered copper, or a copper alloy. According to some aspects, the first metal pattern 146a and the first connection pad 142La each include a same material. For example, in some embodiments, a first metal pattern 146a and a first connection pad 142La each include a copper alloy. According to some aspects, a second metal pattern 146b and a third metal pattern 146c each include a same material as a fourth connection pad 142Ld. For example, in some embodiments, a second metal pattern 146b, a third metal pattern 146c, and a fourth connection pad 142Ld each include a copper alloy.

According to some aspects, the molding layer 150 is disposed in the cavity 140C. According to some aspects, the molding layer 150 is disposed between the semiconductor chip 130 and the connection structure 140. In some embodiments, the molding layer 150 fills a space between the plurality of base layers 144 and the semiconductor chip 130 in the cavity 140C. In some embodiments, the molding layer 150 covers a top surface in the first direction D1 of each of the connection structure 140 and the semiconductor chip 130. In some embodiments, the molding layer 150 includes an epoxy-based material, a thermosetting material, or a thermoplastic material. For example, the molding layer 150 may include a material such as Ajinomoto Build-up Film®, flame retardant 4 (FR-4), Bismaleimide Triazine (BT), epoxy molding compound (EMC), or the like.

According to some aspects, a second redistribution structure 160 is disposed on the semiconductor chip 130. In some embodiments, the second redistribution structure 160 includes a plurality of second redistribution patterns 162 and one or more second redistribution insulation layers 164. In some embodiments, the second redistribution insulation layer 164 covers at least a portion of the plurality of second redistribution patterns 162. In some embodiments, the second redistribution insulation layer 164 includes a photoimageable dielectric (PID) material, an Ajinomoto Build-up Film® material, a solder resist (SR) material, an epoxy molding compound (EMC) material, a flame retardant 4 (FR-4) material, or a Bismaleimide Triazine (BT) material.

According to some aspects, the second redistribution structure 160 includes a plurality of second redistribution line patterns 162L and a plurality of second redistribution via patterns 162V. In some embodiments, a second redistribution pattern 162 includes a second redistribution line pattern 162L and a second redistribution via pattern 162V.

According to some aspects, the plurality of second redistribution line patterns 162L extend in the horizontal direction (e.g., in the second direction D2) on a top surface and/or a bottom surface in the first direction D1 of the second redistribution insulation layer 164. In some embodiments, some second redistribution line patterns 162L are located at a vertical level different from that at which other second redistribution line patterns 162L are located. In some embodiments, some second redistribution line patterns 162L are disposed on a different level in the first direction D1 from other second redistribution line patterns 162L.

According to some aspects, the plurality of second redistribution via patterns 162V extend in the vertical direction (e.g., in the first direction D1) within the second redistribution insulation layer 164 and/or within the molding layer 150. In some embodiments, the plurality of second redistribution via patterns 162V extend in the horizontal direction (e.g., in the second direction D2) within the second redistribution insulation layer 164 and/or within the molding layer 150.

According to some aspects, the plurality of second redistribution via patterns 162V interconnect second redistribution line patterns 162L located at different vertical levels. For example, in some embodiments, a second redistribution via pattern 162V connects a pair of second redistribution line patterns disposed on different levels in the first direction D1 from each other. According to some aspects, the plurality of second redistribution via patterns 162V interconnect at least some lowermost second redistribution line patterns 162L in the first direction D1 among the plurality of second redistribution line patterns 162L and at some fourth connection pads 142Ld of the connection structure 140. In some embodiments, a second redistribution via pattern 162V connects a lowermost second redistribution line pattern 162L in the first direction D1 and a fourth connection pad 142Ld.

According to some aspects, one or more second redistribution via patterns 162V has a tapered shape such that a horizontal width (e.g., a width in the second direction D2) of the second redistribution via pattern 162V increases in a direction away from a top surface of the semiconductor chip 130 (e.g., a top surface in the first direction D1). For example, in some embodiments, a higher portion in the first direction D1 of a second redistribution via pattern 162V is wider in the second direction D2 than a lower portion in the first direction D1 of the second redistribution via pattern 162V.

According to some aspects, one or more second redistribution patterns 162 include copper (Cu), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

According to some aspects, a plurality of connection pads 172 are arranged or disposed on at least a portion of an uppermost second redistribution line pattern 162L in the first direction D1 from among the plurality of second redistribution line patterns 162L of the second redistribution structure 160. In some embodiments, one or more connection pads 172 respectively contact one or more uppermost second redistribution line patterns 162L. In some embodiments, a connection pad 172 contacts an uppermost second redistribution line pattern 162L. In some embodiments, one or more connection pads 172 include nickel (Ni), gold (Au), or a combination thereof.

According to some aspects, one or more connection pads 172 are at least partially surrounded by an upper insulation layer 174. According to some aspects, the upper insulation layer 174 comprises an insulating material. In some embodiments, the upper insulation layer 174 includes a photoimageable dielectric (PID) material, an Ajinomoto Build-up Film® material, a solder resist (SR) material (e.g., a solder mask material), an epoxy molding compound (EMC) material, a flame retardant 4 (FR-4) material, or a Bismaleimide Triazine (BT) material. For example, in some embodiments, the upper insulation layer 174 includes a PID material layer.

According to some aspects, the upper insulation layer 174 includes a plurality of first holes H1. In some embodiments, a first hole H1 exposes a least a portion of a top surface in the first direction D1 of a connection pad 172. In some embodiments, the semiconductor package 100 described with reference to FIGS. 1 and 2 is a lower semiconductor package comprising a package-on-package (POP) type semiconductor package, and a plurality of external connection terminals interconnecting an upper semiconductor package and the lower semiconductor package 100 are arranged in the plurality of first holes H1, respectively. In some embodiments, an external connection terminal contacts a portion of a top surface of a connection pad 172 exposed by a first hole H1.

According to some aspects, the semiconductor package 100 includes one or more metal patterns 146 including a first metal pattern 146a provided between a first redistribution insulation layer 114 of a first redistribution structure 110 and a plurality of base layers 144. Therefore, in some embodiments, the first base layer 144a and the first redistribution insulation layer 114 of the first redistribution structure 110 may not contact each other in a lower portion of a cavity 140C in which the first metal pattern 146a is disposed. Accordingly, in some embodiments, in a process of forming the first redistribution insulation layer 114 on the first base layer 144a, it is possible to prevent a defect in the first base layer 144a, such as a crack, from causing a defect in the first redistribution insulation layer 114 formed on the first base layer 144a, such as a pore. Therefore, in some embodiments, a structural reliability of the semiconductor package 100 is increased.

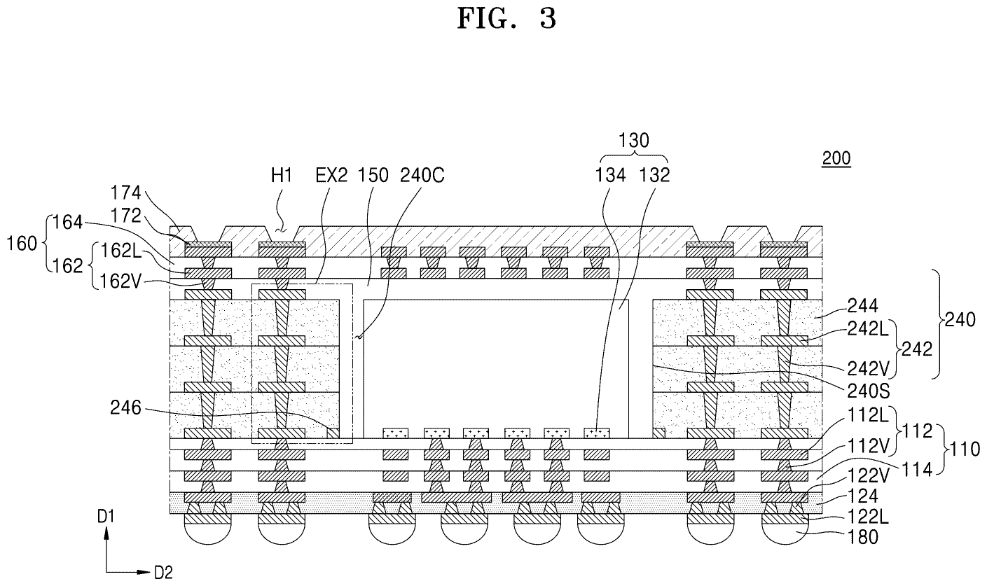

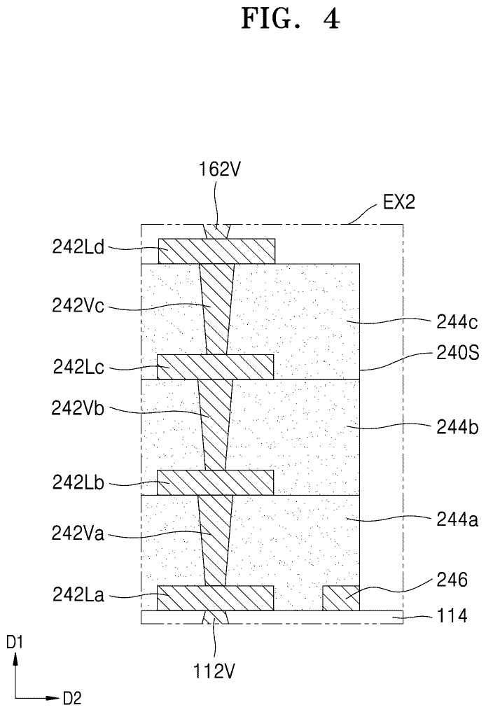

FIG. 3 is a cross-sectional view of a semiconductor package 200 according to an embodiment of the inventive concept. FIG. 4 is an enlarged cross-sectional view of a portion EX2 of FIG. 3 according to an embodiment of the inventive concept. In FIGS. 3 and 4, same reference numerals as those used in FIGS. 1 and 2 indicate similar elements, and thus repeated descriptions of the similar elements are omitted for the sake of brevity.

Referring to FIGS. 3 and 4, according to some aspects, the semiconductor package 200 includes a substantially similar configuration as the semiconductor package 100 described with reference to FIGS. 1 and 2. However, in some embodiments, the semiconductor package 200 includes a connection structure 240 including one or more metal patterns 246. According to some aspects, the connection structure 240 includes a plurality of base layers 244 and a plurality of via structures 242.

According to some aspects, the plurality of base layers 244 includes a first base layer 244a, a second base layer 244b, and a third base layer 244c. In some embodiments, the first base layer 244a, the second base layer 244b, and the third base layer 244c are stacked in the vertical direction (e.g., in the first direction D1). In some embodiments, the plurality of base layers 244 include a substantially similar structure as the plurality of base layers 144 of the semiconductor package 100 described with reference to FIGS. 1 and 2. In some embodiments, one or more base layers 244 include a substantially similar material as one or more base layers 144.

According to some aspects, the connection structure 240 includes a plurality of connection pads 242L and a plurality of connection via patterns 242V. According to some aspects, one or more via structures 242 include a connection pad 242L and a connection via pattern 242V. In some embodiments, the plurality of connection pads 242L includes one or more first connection pads 242La, one or more second connection pads 242 Lb, one or more third connection pads 242Lc, and one or more fourth connection pads 242Ld located at different vertical levels. For example, in some embodiments, a first connection pad 242La, a second connection pad 242 Lb, a third connection pad 242Lc, and a fourth connection pad 242Ld are disposed on different levels in the first direction D1 from each other.

According to some aspects, the plurality of connection via patterns 242V includes one or more first connection via patterns 242Va, one or more second connection via patterns 242Vb, and one or more third connection via patterns 242Vc located at different vertical levels. For example, in some embodiments, a first connection via pattern 242Va, a second connection via pattern 242Vb, and a third connection via pattern 242Vc are disposed on different levels in the first direction D1 from each other. In some embodiments, the plurality of via structures 242 include a substantially similar structure as the plurality of via structures 142 of the semiconductor package 100 described with reference to FIGS. 1 and 2. In some embodiments, one or more via structures 242 include a substantially similar material as one or more via structures 142.

According to some aspects, a metal pattern 246 is disposed on an inner surface 240S of the connection structure 240. In some cases, the inner surface 240S is a surface of one or more base layers 244, where the inner surface 240S extends in the first direction D1 and faces away from the one or more base layers 244 and toward the semiconductor chip 130 and/or a cavity 240C. In some embodiments, a metal pattern 246 is disposed on a top surface in the first direction D1 of the first redistribution structure 110 and extends in a horizontal direction (e.g., in the second direction D2) from an inner surface 240S of the connection structure 240 into a first base layer 244a disposed at a bottom of the plurality of base layers 244 in the vertical direction (e.g., in the first direction D1). In some embodiments, the metal pattern 246 is horizontally spaced apart (e.g., spaced apart in the second direction D2) from a first connection pad 242La. In some embodiments, the first base layer 244a is disposed between the metal pattern 246 and the first connection pad 242La.

According to some aspects, in a region where the metal pattern 246 is disposed, the first base layer 244a and the uppermost first redistribution insulation layer from among the plurality of first redistribution insulation layers 114 are spaced apart from each other in a vertical direction (e.g., in the first direction D1) with the metal pattern 246 therebetween. Accordingly, in some embodiments, in the region where the metal pattern 246 is disposed, the first base layer 244a and the first redistribution insulation layer 114 do not contact each other.

According to some aspects, at least a portion of the first base layer 244a and at least a portion of the uppermost first redistribution insulation layer are spaced apart from each other in the first direction D1. In some embodiments, the metal pattern 246 is disposed between at least the portion of the first base layer 244a and at least the portion of the uppermost first redistribution insulation layer. In some embodiments, at least the portion of the first base layer 244a and at least the portion of the uppermost first redistribution insulation layer do not contact each other.

According to some aspects, a metal pattern 246 is located at (e.g., disposed on) a same vertical level (e.g., a same level in the first direction D1) as a first connection pad 242La. In some embodiments, a length of a metal pattern 246 in the vertical direction (e.g., in the first direction D1) is equal to a length of a first connection pad 242La in the vertical direction (e.g., in the first direction D1).

According to some aspects, a metal pattern 246 includes a top surface in the first direction D1, extending in the second direction D2. According to some aspects, the metal pattern 246 includes an inner surface extending in the first direction D1. According to some aspects, the metal pattern 246 includes an outer surface extending in the first direction D1. In some embodiments, the inner surface of the metal pattern 246 is spaced apart from the outer surface of the metal pattern 246 in the second direction D2. In some embodiments, the outer surface of the metal pattern 246 is further from the semiconductor chip 130 in the second direction D2 than the inner surface of the metal pattern 246. In some embodiments, the inner surface of the metal pattern 246 is a surface facing away from the plurality of base layers 244 and toward the semiconductor chip 130 and/or the cavity 240C.

According to some aspects, a top surface of the metal pattern 246 and an outer surface of the metal pattern 246 are surrounded by a first base layer 242a. According to some aspects, an inner surface of the metal pattern 246 is surrounded by the molding layer 150. According to some aspects, an inner surface of the metal pattern 246 is located on (e.g., disposed on) a same plane as an inner surface 240S of the connection structure 240 and an outer surface of the molding layer 150 (e.g., a surface of the molding layer 150 facing away from the semiconductor chip 130 and toward the plurality of base layers 244, and/or a surface of the molding layer 150 contacting one or more base layers 244).

According to some aspects, the metal pattern 246 corresponds to the first metal pattern 146a of the semiconductor package 100 described with reference to FIGS. 1 and 2. For example, in some embodiments, structures corresponding to the second metal pattern 146b and the third metal pattern 146c of the semiconductor package 100 are omitted in the semiconductor package 200 described with reference to FIGS. 3 and 4.

According to some aspects, one or more metal patterns 246 include an ED copper foil, an RA a copper foil, a stainless steel foil, an aluminum foil, an ultra-thin copper foil, sputtered copper, or a copper alloy. In some embodiments, one or more metal patterns 246 and one or more first connection pads 242La include a same material. For example, in some embodiments, a metal pattern 246 and a first connection pad 242La each include a copper alloy.

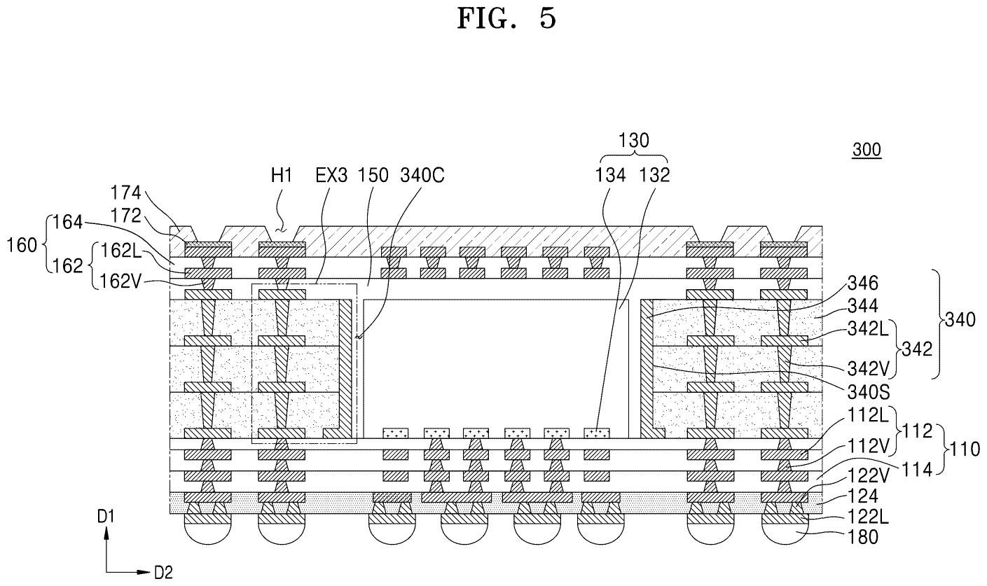

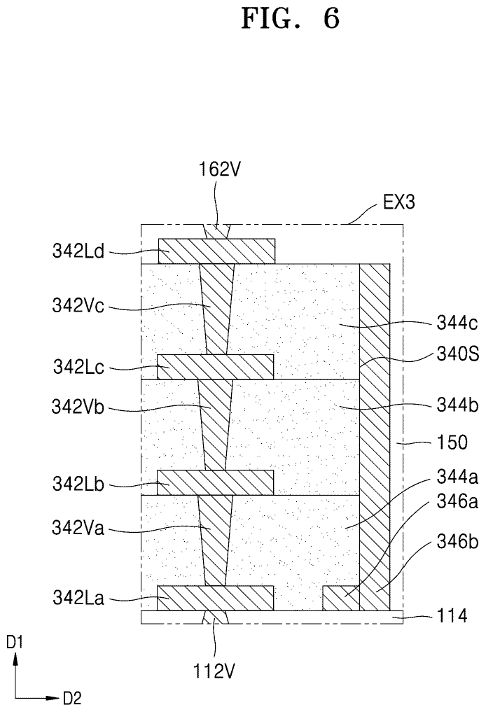

FIG. 5 is a cross-sectional view of a semiconductor package 300 according to an embodiment of the inventive concept. FIG. 6 is an enlarged cross-sectional view of a portion EX3 of FIG. 5 according to an embodiment of the inventive concept. In FIGS. 5 and 6, same reference numerals as those used in FIGS. 1 and 2 indicate similar elements, and thus repeated descriptions of the similar elements are omitted for the sake of brevity.

Referring to FIGS. 5 and 6, according to some aspects, the semiconductor package 300 includes a substantially similar configuration as the semiconductor package 100 shown in FIGS. 1 and 2. However, in some embodiments, the semiconductor package 300 includes a connection structure 340 including one or more metal patterns 346. According to some aspects, the connection structure 340 includes a plurality of base layers 344 and a plurality of via structures 342.

According to some aspects, the plurality of base layers 344 includes a first base layer 344a, a second base layer 344b, and a third base layer 344c. In some embodiments, the first base layer 344a, the second base layer 344b, and the third base layer 344c are stacked in the vertical direction (e.g., in the first direction D1). In some embodiments, the plurality of base layers 344 include a substantially similar structure as the plurality of base layers 144 of the semiconductor package 100 described with reference to FIGS. 1 and 2. In some embodiments, one or more base layers 344 include a substantially similar material as one or more base layers 144.

According to some aspects, the connection structure 340 includes a plurality of via connection pads 342L and a plurality of connection via patterns 342V. According to some aspects, one or more via structures 342 include a connection pad 342L and a connection via pattern 342V. In some embodiments, the plurality of connection pads 342L includes one or more first connection pads 342La, one or more second connection pads 342 Lb, one or more third connection pads 342Lc, and one or more fourth connection pads 342Ld located at different vertical levels. For example, in some embodiments, a first connection pad 342La, a second connection pad 342 Lb, a third connection pad 342Lc, and a fourth connection pad 342Ld are disposed on different levels in the first direction D1 from each other.

According to some aspects, the plurality of connection via patterns 342V includes one or more first connection via patterns 342Va, one or more second connection via patterns 342Vb, and one or more third connection via patterns 342Vc located at different vertical levels. For example, in some embodiments, a first connection via pattern 342Va, a second connection via pattern 342Vb, and a third connection via pattern 342Vc are disposed on different levels in the first direction D1 from each other. In some embodiments, the plurality of via structures 342 include a substantially similar structure as the plurality of via structures 142 of the semiconductor package 100 described with reference to FIGS. 1 and 2. In some embodiments, one or more via structures 342 include a substantially similar material as one or more via structures 142.

According to some aspects, a metal pattern 346 is disposed on an inner surface 340S of the connection structure 340. In some cases, the inner surface 340S is a surface of one or more base layers 344, where the inner surface 340S extends in the first direction D1 and faces away from the one or more base layers 344 and toward the semiconductor chip 130 and/or a cavity 340C. In some embodiments, a metal pattern 346 includes a first metal pattern 346a and a second metal pattern 346b. In some embodiments, the first metal pattern 346a is disposed on a top surface in the first direction D1 of the first redistribution structure 110 and extends in the horizontal direction (e.g., in the second direction D2) from an inner surface 340S of the connection structure 340 into a first base layer 344a disposed at a bottom of the plurality of base layers 344 in the vertical direction (e.g., in the first direction D1). In some embodiments, the first metal pattern 346a is horizontally spaced apart (e.g., spaced apart in the second direction D2) from a first connection pad 342La.

According to some aspects, in a region where the first metal pattern 346a is disposed, the first base layer 344a and the uppermost first redistribution insulation layer from among first redistribution insulation layers 114 are spaced apart from each other in a vertical direction (e.g., in the first direction D1) with the first metal pattern 346a therebetween. Accordingly, in some embodiments, in the region where the first metal pattern 346a is disposed, the first base layer 344a and the first redistribution insulation layer 114 do not contact each other.

According to some aspects, at least a portion of the first base layer 344a and at least a portion of the uppermost first redistribution insulation layer are spaced apart from each other in the first direction D1. In some embodiments, the first metal pattern 346a is disposed between at least the portion of the first base layer 344a and at least the portion of the uppermost first redistribution insulation layer. In some embodiments, at least the portion of the first base layer 344a and at least the portion of the uppermost first redistribution insulation layer do not contact each other.

According to some aspects, a first metal pattern 346a and a first connection pad 342La are located at the same vertical level. For example, in some embodiments, a first metal pattern 346a and a first connection pad 342La are disposed on a same level in the first direction D1 as each other. According to some aspects, a length of the first metal pattern 346a in the vertical direction (e.g., in the first direction D1) is equal to a length of a first connection pad 342La in the vertical direction (e.g., in the first direction D1).

According to some aspects, a first metal pattern 346a includes a top surface in the first direction D1, extending in the second direction D2. According to some aspects, the first metal pattern 346a includes an inner surface extending in the first direction D1. According to some aspects, the first metal pattern 346a includes an outer surface extending in the first direction D1. In some embodiments, the inner surface of the first metal pattern 346a is spaced apart from the outer surface of the first metal pattern 346a in the second direction D2. In some embodiments, the outer surface of the first metal pattern 346a is further from the semiconductor chip 130 in the second direction D2 than the inner surface of the first metal pattern 346a. In some embodiments, the inner surface of the first metal pattern 346a is a surface facing away from the plurality of base layers 344 and toward the semiconductor chip 130 and/or the cavity 340C.

According to some aspects, a top surface in the first direction D1 of the first metal pattern 346a and an outer surface of the first metal pattern 346a are surrounded by the first base layer 344a. According to some aspects, an inner surface of a first metal pattern 346a contacts the second metal pattern 346b. According to some aspects, an inner surface of the first metal pattern 346a is located on (e.g., disposed on) a same plane as an inner surface 340S of the connection structure 340.

According to some aspects, a second metal pattern 346b is disposed on an inner surface of the first metal pattern 346a. In some cases, the second metal pattern 346b extends in the vertical direction (e.g., in the first direction D1) on the inner surface of the first metal pattern 346a.

According to some aspects, a top surface in the first direction D1 of the second metal pattern 346b is located on (e.g., disposed on) a same plane as a bottom surface in the first direction D1 of a fourth connection pad 342Ld. According to some aspects, the top surface of the second metal pattern 346b is covered by the molding layer 150. According to some aspects, a horizontal width (e.g., a width in the second direction D2) of a second metal pattern 346b is equal to a length of a fourth connection pad 342Ld in the vertical direction (e.g., in the first direction D1).

According to some aspects, a second metal pattern 346b includes an inner surface extending in the first direction D1. According to some aspects, the second metal pattern 346b includes an outer surface extending in the first direction D1. In some embodiments, the inner surface of the second metal pattern 346b is spaced apart from the outer surface of the second metal pattern 346b in the second direction D2. In some embodiments, the outer surface of the second metal pattern 346b is further from the semiconductor chip 130 in the second direction D2 than the inner surface of the second metal pattern 346b. In some embodiments, the inner surface of the second metal pattern 346b is a surface facing away from the plurality of base layers 344 and toward the semiconductor chip 130 and/or the cavity 340C.

According to some aspects, the first metal pattern 346a and the second metal pattern 346b respectively correspond to the first metal pattern 146a and the second metal pattern 146b of the semiconductor package 100 described with reference to FIGS. 1 and 2. For example, in some embodiments, a structure corresponding to a third metal pattern 146c of the semiconductor package 100 is omitted in the semiconductor package 300 described with reference to FIGS. 5 and 6.

According to some aspects, one or more first metal patterns 346a and one or more second metal patterns 346b each include an ED copper foil, an RA copper foil, a stainless steel foil, an aluminum foil, an ultra-thin copper foil, sputtered copper, or a copper alloy. According to some aspects, one or more first metal patterns 346a and one or more first connection pads 342La each include a same material. For example, in some embodiments, a first metal pattern 346a and a first connection pad 342La each include a copper alloy. According to some aspects, one or more second metal patterns 346b and one or more fourth connection pads 342Ld each include a same material. For example, in some embodiments, a second metal pattern 346b and a fourth connection pad 342Ld each include a copper alloy.

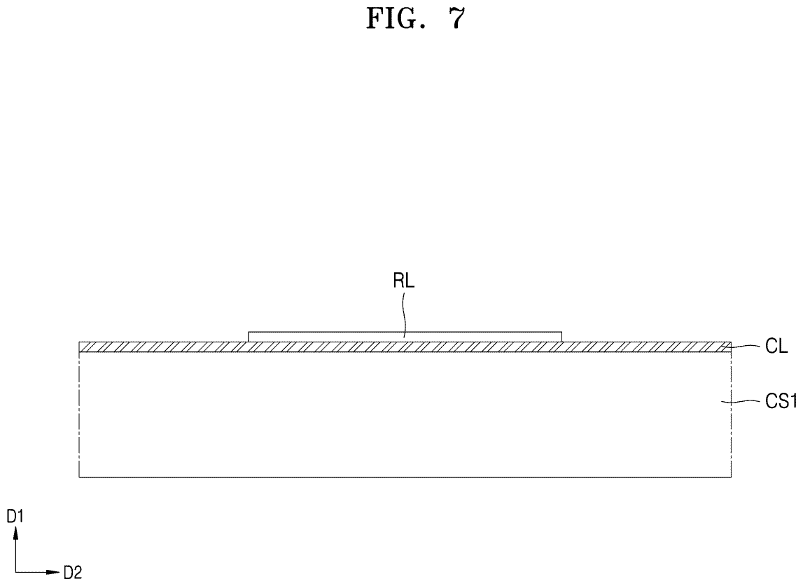

FIGS. 7 to 20 are cross-sectional views for describing a method of manufacturing the semiconductor package 100 according to an embodiment of the inventive concept.

Referring to FIG. 7, in some embodiments, a first carrier film CS1 is provided and a metal layer CL is formed on a top surface in the first direction D1 of the first carrier film CS1. In some embodiments, a release layer RL is formed on the metal layer CL of the first carrier film CS1. In some embodiments, the first carrier film CS1 comprises a copper clad laminate, such as deformed copper foil (DCF). In some embodiments, the metal layer CL and the first connection pad 142La described with reference to FIGS. 1 and 2 each include a substantially similar material.

In some embodiments, FIG. 8 shows a successive structure from the structure shown in FIG. 7. Referring to FIG. 8, in some embodiments, a first connection pad 142La and a first metal pattern 146a are formed. For example, in some embodiments, a patterned mask is formed on the metal layer CL, and the first connection pad 142La and the first metal pattern 146a are formed by using the metal layer CL as a seed layer. In some embodiments, the first connection pad 142La and the first metal pattern 146a may be formed through, for example, an electrolytic plating process or an electroless plating process. In some embodiments, because the first connection pad 142La and the first metal pattern 146a are simultaneously formed using the metal layer CL as a seed layer, the first connection pad 142La and the first metal pattern 146a include substantially similar material as each other. In some embodiments, because the first connection pad 142La and the first metal pattern 146a are simultaneously formed using a same patterned mask, a length of the first connection pad 142La in the vertical direction (e.g., in the first direction D1) and a length of the first metal pattern 146a in the vertical direction (e.g., in the first direction D1) are equal.

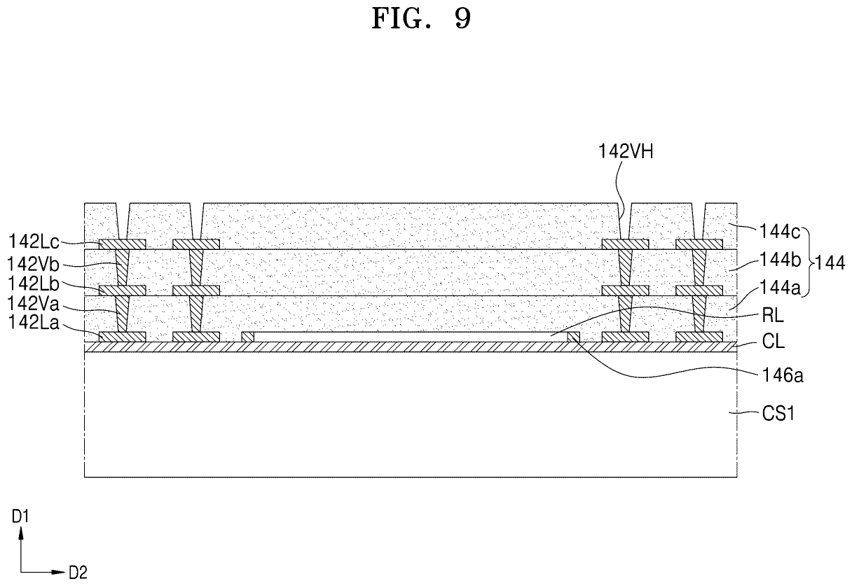

In some embodiments, FIG. 9 shows a successive structure from the structure shown in FIG. 8. Referring to FIG. 9, in some embodiments, a first base layer 144a, a second base layer 144b, a third base layer 144c, a second connection pad 142 Lb, a third connection pad 142Lc, a first connection via pattern 142Va, and a second connection via pattern 142Vb are formed. For example, in some embodiments, a first base layer 144a covering the first connection pad 142La, the first metal pattern 146a, and the release layer RL is formed, a via hole overlapping the first connection pad 142La in the vertical direction (e.g., the first direction D1) and penetrating through the first base layer 144a in the vertical direction (e.g., the first direction D1) is formed, the first connection via pattern 142Va is formed by filling the via hole, and the second connection pad 142 Lb connected to the first connection via pattern 142Va is formed on the first base layer 144a. Thereafter, in some embodiments, by repeatedly performing the above-described operations, a second base layer 144b, the third connection pad 142Lc, and the second connection via pattern 142Vb are formed. In some embodiments, after forming the third base layer 144c covering the third connection pad 142Lc, a plurality of via holes 142VH overlapping the third connection pad 142Lc in the vertical direction (e.g., the first direction D1) and penetrating through the third base layer 144c in the vertical direction (e.g., the first direction D1) are formed.

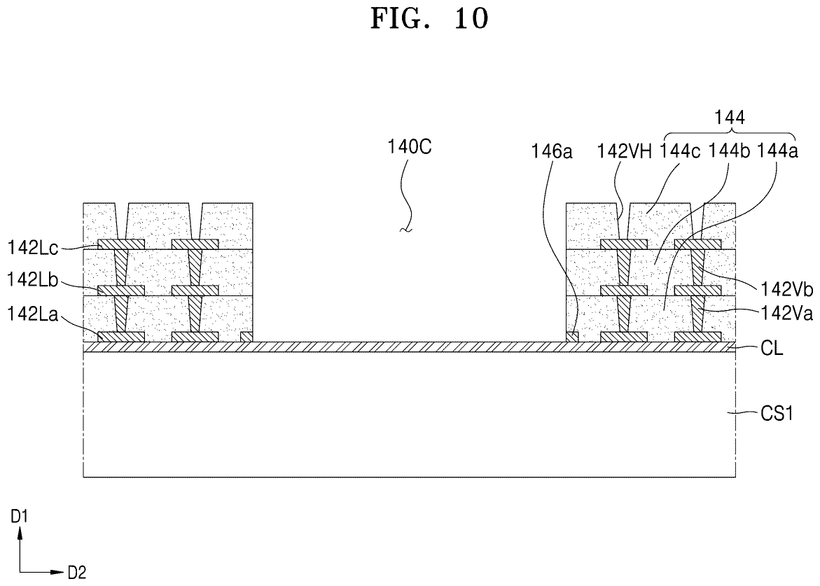

In some embodiments, FIG. 10 shows a successive structure from the structure shown in FIG. 9. Referring to FIG. 10, in some embodiments, central regions of the first base layer 144a, the second base layer 144b, and the third base layer 144c that overlap the release layer RL (refer to FIG. 9) in the vertical direction (e.g., in the first direction D1) are removed, exposing the metal layer CL, and thereby forming the cavity 140C.

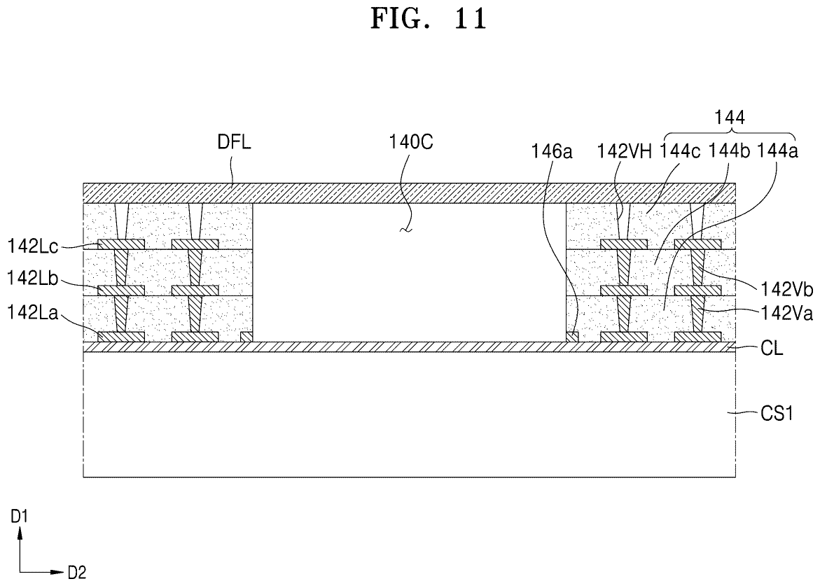

In some embodiments, FIG. 11 shows a successive structure from the structure shown in FIG. 10. Referring to FIG. 11, in some embodiments, a photoresist composition layer DFL is formed on a top surface in the first direction D1 of the third base layer 144c. In some embodiments, the photoresist composition layer DFL covers the plurality of via holes 142VH and the cavity 140C formed in the third base layer 144c. In some embodiments, the photoresist composition layer DFL comprises, for example, a dry film photoresist composition layer or the like.

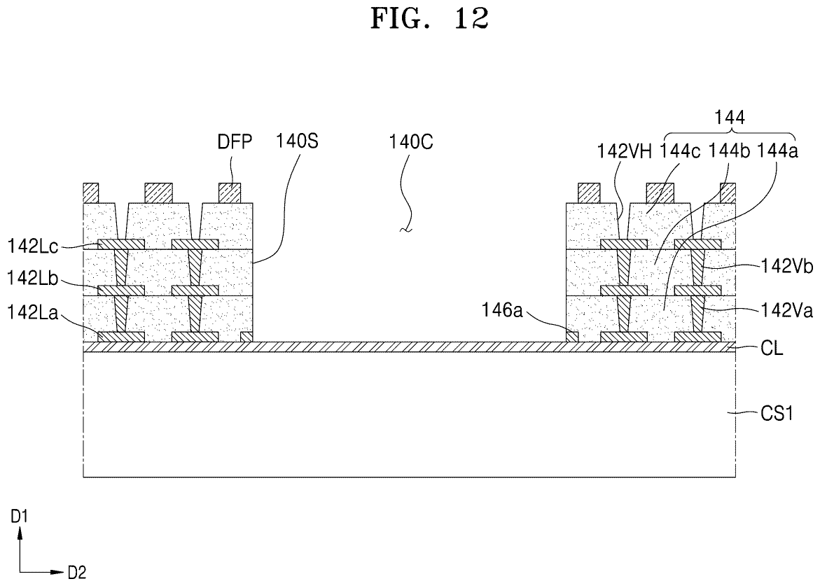

In some embodiments, FIG. 12 shows a successive structure from the structure shown in FIG. 11. Referring to FIG. 12, in some embodiments, a photolithography process is performed using the photoresist composition layer DFL (refer to FIG. 11), thereby forming a photoresist pattern DFP. In some embodiments, the photoresist pattern DFP includes a plurality of openings. In some embodiments, the plurality of openings correspond to regions in which the fourth connection pad 142Ld and the third metal pattern 146c described with reference to FIGS. 1 and 2 are formed.

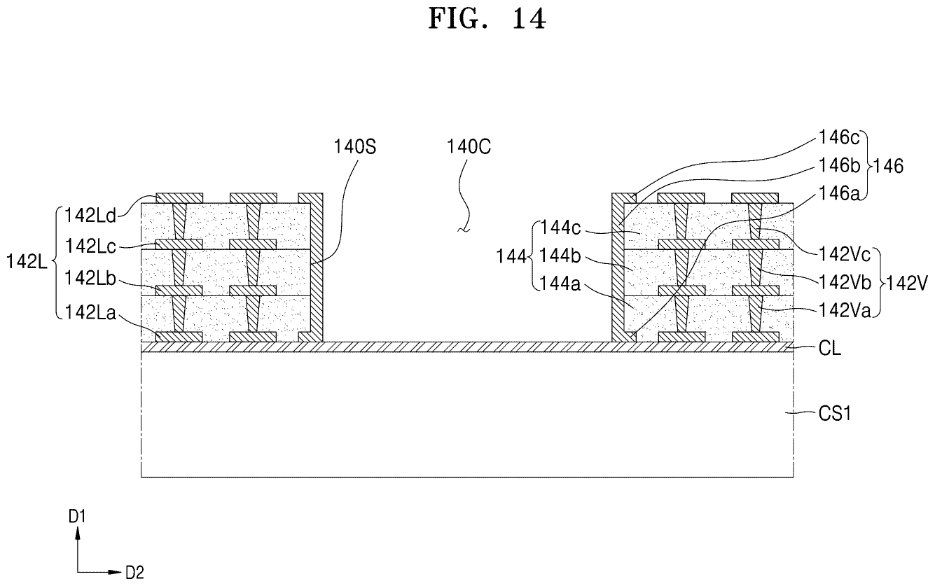

According to some aspects, the photoresist pattern DFP may expose a region in which the fourth connection pad 142Ld described with reference to FIGS. 1 and 2 is formed and covers a region in which the third metal pattern 146c described with reference to FIGS. 1 and 2 is formed. In this case, the third metal pattern 146c is not formed using a process described with reference to FIG. 13. Thereafter, the semiconductor package 300 described with reference to FIGS. 5 and 6 may be manufactured by performing the manufacturing process described with reference to FIGS. 14 to 20.

In some embodiments, FIG. 13 shows a successive structure from the structure shown in FIG. 12. Referring to FIG. 13, in some embodiments, the fourth connection pad 142Ld, the third connection via pattern 142Vc, the second metal pattern 146b, and the third metal pattern 146c are formed. For example, in some embodiments, a seed layer is formed on a surface of the third base layer 144c exposed by the photoresist pattern DFP, in and/or on the plurality of via holes 142VH (refer to FIG. 12), on a surface of the metal layer CL exposed by the cavity 140C, and on surfaces of the first base layer 144a, the second base layer 144b, and the third base layer 144c. In some embodiments, a plating process is performed using the seed layer, thereby respectively forming a fourth connection pad 142Ld and a third connection via pattern 142Vc on a surface of the third base layer 144c exposed by the photoresist pattern DFP and in a via hole 142VH (refer to FIG. 12), and respectively forming a second metal pattern 146b and a third metal pattern 146c on surfaces of the first base layer 144a, second base layer 144b, and third base layer 144c. The plating process may include, for example, an electroless plating process or an electrolytic plating process.

In some embodiments, a metal material layer 146L is formed on a surface of the metal layer CL through the plating process. In some embodiments, the metal material layer 146L is formed simultaneously with the second metal pattern 146b and the third metal pattern 146c, and one or more of the metal material layer 146L, the second metal pattern 146b, and the third metal pattern 146c are integrated into one body.

In some embodiments, FIG. 14 shows a successive structure from the structure shown in FIG. 13. Referring to FIG. 14, in some embodiments, the photoresist pattern DFP is removed from the surface of the third base layer 144c. In some embodiments, by removing the photoresist pattern DFP, the top surface of the third base layer 144c is exposed. In some embodiments, the metal material layer 146L formed on the surface of the metal layer CL is then removed. In some embodiment, the metal material layer 146L is removed through, for example, a wet etching process or a dry etching process.

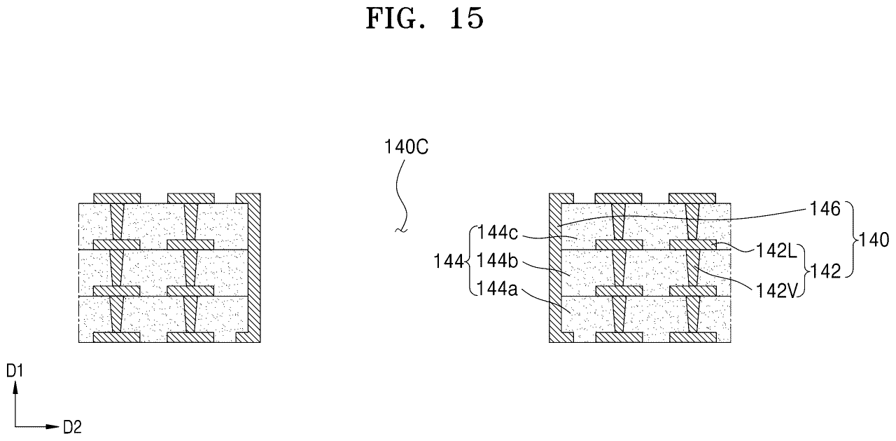

In some embodiments, FIG. 15 shows a successive structure from the structure shown in FIG. 14. Referring to FIG. 15, in some embodiments, the connection structure 140 is formed by removing the metal layer CL and the first carrier film CS1.

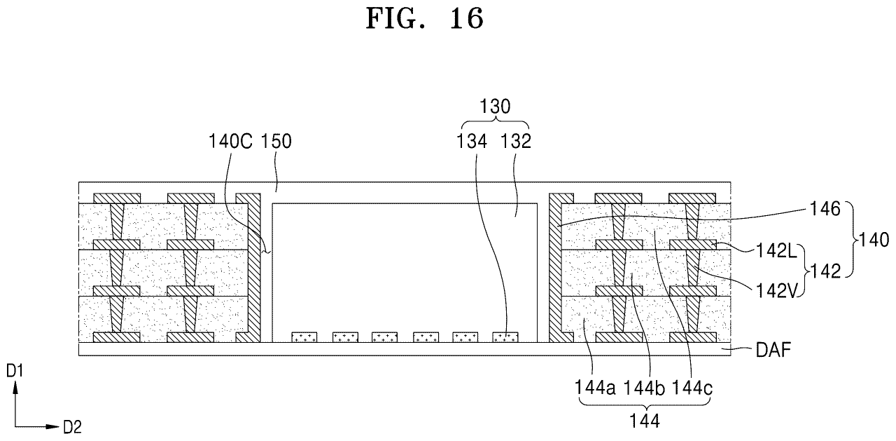

According to some aspects, manufacturing processes described with reference to FIGS. 11 to 14 may be omitted. In this case, the manufacturing process described with reference to FIG. 9 is performed, a third connection via pattern 142Vc filling a via hole 142VH is formed, a fourth connection pad 142Ld connected to a third connection via pattern 142Vc is formed, the cavity 140C is formed as described with reference to FIG. 10, the release layer RL is removed, and the first carrier film CS1 and the metal layer CL are removed as described with reference to FIG. 15. Thereafter, in some embodiments, the semiconductor package 200 shown in FIGS. 3 and 4 may be manufactured by performing the manufacturing process described with reference to FIGS. 16 to 20.

In some embodiments, FIG. 16 shows a successive structure from the structure shown in FIG. 15. Referring to FIG. 16, in some embodiments, a support film DAF is attached to a bottom surface in the first direction D1 of the connection structure 140. In some embodiments, the semiconductor chip 130 is then attached to the cavity 140C of the connection structure 140, and the molding layer 150 is formed. In some embodiments, the semiconductor chip 130 is disposed such that a bottom surface in the first direction D1 of the semiconductor chip 130 on which the chip pads 134 of the semiconductor chip 130 are formed faces the support film DAF.

In some embodiments, the semiconductor chip 130 is horizontally spaced apart (e.g., spaced apart in the second direction D2) from the inner surface 140S of the connection structure 140. In some embodiments, the molding layer 150 is formed to fill a space between the semiconductor chip 130 and the inner surface of the cavity 140C and to cover surfaces of the plurality of base layers 144 and the semiconductor chip 130. In some embodiments, the molding layer 150 fixes the semiconductor chip 130 in place.

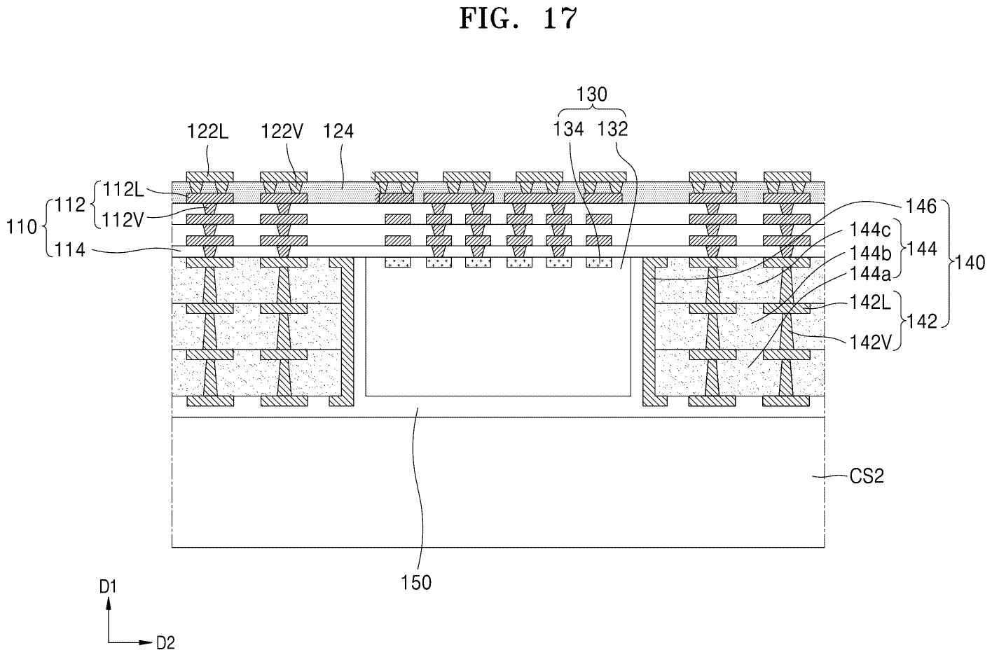

In some embodiments, FIG. 17 shows a successive structure from the structure shown in FIG. 16. Referring to FIG. 17, in some embodiments, a first carrier substrate CS2 is attached to a top surface in the first direction D1 of the molding layer 150 facing a bottom surface in the first direction D1 of the connection structure 140 to which the support film DAF is attached, and the support film DAF (refer to FIG. 16) is removed from the bottom surface of the connection structure 140. In some embodiments, the first carrier substrate CS2 includes a glass substrate, a silicon substrate, a metal substrate, or a combination thereof.

In some embodiments, the first redistribution structure 110 is then formed on a surface of the semiconductor chip 130 on which the chip pads 134 are formed. In some embodiments, the first redistribution structure 110 is formed by repeating the process of forming the first redistribution insulation layer 114 on the surface of the semiconductor chip 130 on which the chip pads 134 are formed, forming a first redistribution via pattern 112V penetrating through the first redistribution insulation layer 114 in the vertical direction (e.g., in the first direction D1), and forming a first redistribution line pattern 112L connected to the first redistribution via pattern 112V on the first redistribution insulation layer 114. In some embodiments, the surface of an outermost (e.g., an uppermost in the first direction D1) first redistribution line pattern 112L is therefore exposed without being covered by the first redistribution insulation layer 114.

In some embodiments, a lower insulation layer 124 is then formed on the first redistribution structure 110. In some embodiments, after the plurality of conductive via patterns 122V penetrating through the lower insulation layer 124 are formed, the plurality of conductive pads 122L connected to the plurality of conductive via patterns 122V are formed.

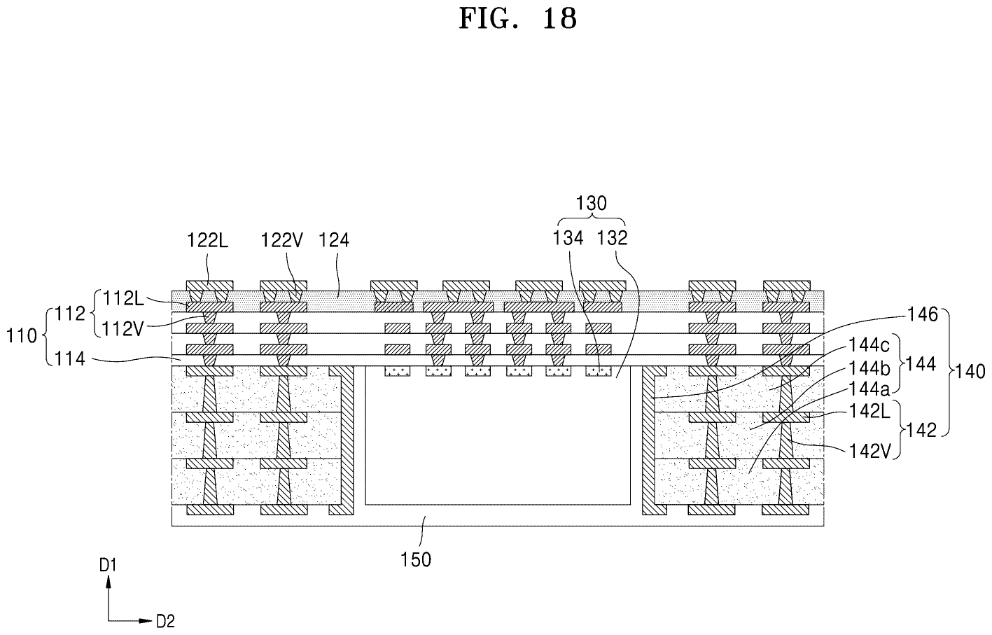

In some embodiments, FIG. 18 shows a successive structure from the structure shown in FIG. 17. Referring to FIG. 18, in some embodiments, the first carrier substrate CS2 (refer to FIG. 17) is removed from the top surface in the first direction D1 of the molding layer 150.

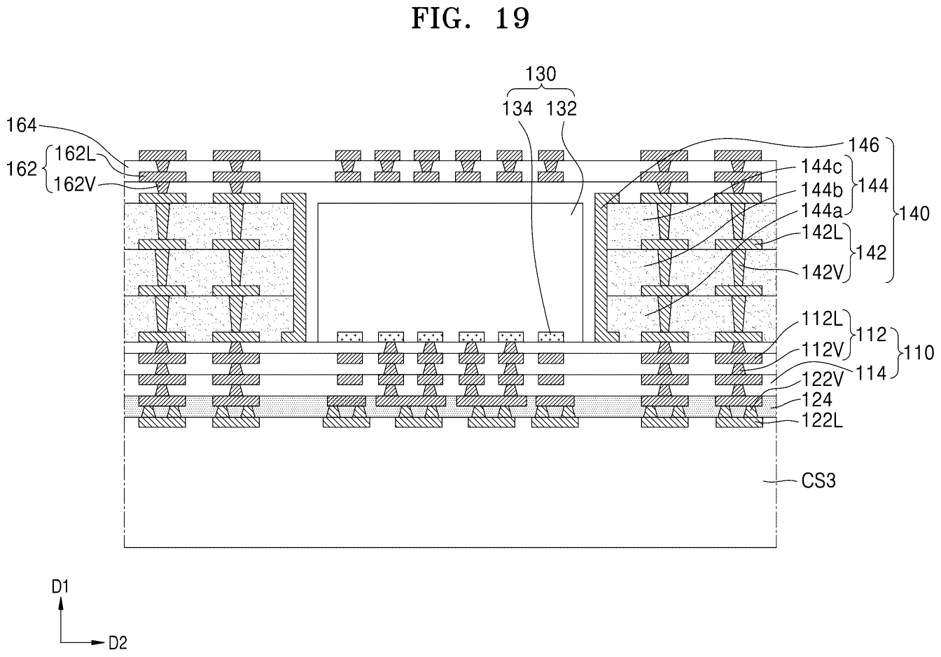

In some embodiments, FIG. 19 shows a successive structure from the structure shown in FIG. 18. Referring to FIG. 19, in some embodiments, a second carrier substrate CS3 is attached to the lower insulation layer 124 and the plurality of conductive pads 122L. In some embodiments, the second carrier substrate CS3 includes a glass substrate, a silicon substrate, a metal substrate, or a combination thereof. In some embodiments, the second redistribution structure 160 is then formed on the top surface of the molding layer 150 from which the first carrier substrate CS2 (refer to FIG. 17) is removed. In some embodiments, the second redistribution structure 160 is formed using a method similar to the method of forming the first redistribution structure 110 described with reference to FIG. 17. In some embodiments, the surface of an outermost (e.g., an uppermost in the first direction D1) second redistribution line pattern 162L of the second redistribution structure 160 is therefore exposed without being covered by the second redistribution insulation layer 164.

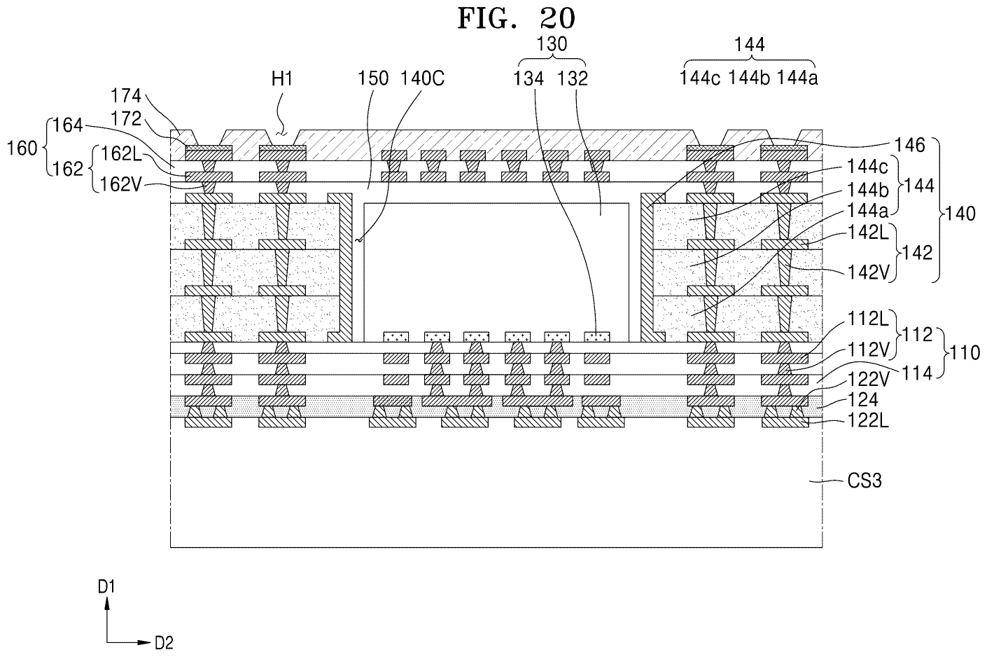

In some embodiments, FIG. 20 shows a successive structure from the structure shown in FIG. 19. Referring to FIG. 20, in some embodiments, the plurality of connection pads 172 are formed on the top surface in the first direction D1 of an outermost (e.g., an uppermost in the first direction D1) second redistribution line pattern 162L. In some embodiments, the plurality of connection pads 172 overlap the outermost second redistribution line pattern 162L in the vertical direction (e.g., in the first direction D1). In some embodiments, the upper insulation layer 174 covering the surface of the outermost second redistribution line pattern 162L and surfaces of the plurality of connection pads 172 is formed, and the plurality of first holes H1 penetrating through the upper insulation layer 174 in the vertical direction (e.g., the first direction D1) and overlapping the plurality of connection pads 172 in the vertical direction (e.g., the first direction D1) are formed. In some embodiments, the plurality of first holes H1 expose one or more top surfaces in the first direction D1 of the plurality of connection pads 172.

In some embodiments, in a successive structure from the structure shown in FIG. 20, the second carrier substrate CS3 attached to the lower insulation layer 124 and the plurality of conductive pads 122L is removed. In some embodiments, the semiconductor package 100 described with reference to FIGS. 1 and 2 is manufactured by forming the plurality of external connection terminals 180 on the plurality of conductive pads 122L exposed by removing the second carrier substrate CS3.

While the inventive concept has been particularly shown and described with reference to embodiments thereof, it will be understood that various changes in form and details may be made therein without departing from the spirit and scope of the present disclosure.

What is claimed is:

1. A semiconductor package comprising:
a redistribution insulation layer;
a connection structure disposed on the redistribution insulation layer in a first direction and comprising a base layer, a metal pattern, and a cavity;
a semiconductor chip disposed on the redistribution insulation layer in the first direction, the semiconductor chip spaced apart from the connection structure; and
a molding layer disposed between the connection structure and the semiconductor chip, wherein the semiconductor chip and the molding layer are disposed in the cavity,
wherein the metal pattern is disposed on the redistribution insulation layer in the first direction and at least partially disposed between the base layer and the molding layer, the metal pattern comprising a first metal pattern extending, in a second direction crossing the first direction, from an inner surface of the connection structure into the base layer and separating at least a portion of the base layer from at least a portion of the redistribution insulation layer.

2. The semiconductor package of claim 1, the connection structure further comprising a plurality of connection pads,
wherein connection pads of the plurality of connection pads are disposed on different levels in the first direction from each other, the plurality of connection pads including a lowermost connection pad in the first direction, and
wherein the first metal pattern and the lowermost connection pad are disposed on a same level in the first direction.

3. The semiconductor package of claim 2, wherein a length of the first metal pattern in the first direction is equal to a length of the lowermost connection pad in the first direction.

4. The semiconductor package of claim 2, wherein the first metal pattern and the lowermost connection pad each include a same material.

5. The semiconductor package of claim 1, the metal pattern further comprising a second metal pattern extending in the first direction and disposed between the first metal pattern and the semiconductor chip.

6. The semiconductor package of claim 5, the connection structure further comprising a plurality of connection pads,
wherein connection pads of the plurality of connection pads are disposed on different levels in the first direction from each other, the plurality of connection pads including an uppermost connection pad in the first direction, and
wherein a top surface in the first direction of the second metal pattern is located on a same plane as a bottom surface in the first direction of the uppermost connection pad.

7. The semiconductor package of claim 6, wherein a width of the second metal pattern in the second direction is equal to a length of the uppermost connection pad in the first direction.

8. The semiconductor package of claim 6, wherein the second metal pattern and the uppermost connection pad each include a same material.

9. A semiconductor package comprising:
a redistribution insulation layer;
a connection structure disposed on the redistribution insulation layer in a first direction and comprising a base layer, a metal pattern, and a cavity;
a semiconductor chip disposed on the redistribution insulation layer in the first direction, the semiconductor chip spaced apart from the connection structure; and
a molding layer disposed between the connection structure and the semiconductor chip, wherein the semiconductor chip and the molding layer are disposed in the cavity;
wherein the metal pattern is disposed on the redistribution insulation layer in the first direction and at least partially between the base layer and the molding layer, the metal pattern comprising:
a first metal pattern extending, in a second direction crossing the first direction, from an inner surface of the connection structure into the base layer and separating at least a portion of the base layer from at least a portion of the redistribution insulation layer;
a second metal pattern disposed on an inner surface of the first metal pattern and extending in the first direction; and
a third metal pattern disposed on a top surface in the first direction of the second metal pattern and extending, in the second direction, from an inner surface of the second metal pattern toward the connection structure.

10. The semiconductor package of claim 9, the connection structure further comprising a plurality of connection pads,
wherein connection pads of the plurality of connection pads are disposed on different levels in the first direction from each other, the plurality of connection pads including a lowermost connection pad in the first direction,
wherein the first metal pattern and the lowermost connection pad are disposed on a same level in the first direction, and
wherein the first metal pattern and the lowermost connection pad each include a same material.

11. The semiconductor package of claim 9, the connection structure further comprising a plurality of connection pads,
wherein connection pads of the plurality of connection pads are disposed on different levels in the first direction from each other, the plurality of connection pads including an uppermost connection pad in the first direction,
wherein a top surface in the first direction of the second metal pattern is located on a same plane as a bottom surface in the first direction of the uppermost connection pad, and
wherein the second metal pattern and the uppermost connection pad each include a same material.

12. The semiconductor package of claim 9, the connection structure further comprising a plurality of connection pads,
wherein connection pads of the plurality of connection pads are disposed on different levels in the first direction from each other, the plurality of connection pads including an uppermost connection pad in the first direction, and
wherein the third metal pattern and the uppermost connection pad are disposed on a same vertical level.

13. The semiconductor package of claim 12, wherein a length of the third metal pattern in the first direction direction is equal to a length of the uppermost connection pad in the first direction.

14. The semiconductor package of claim 12, wherein the third metal pattern and the uppermost connection pad each include a same material.

15. The semiconductor package of claim 9, wherein a width of the second metal pattern in the second direction is equal to a length of the third metal pattern in the first direction.

16. The semiconductor package of claim 9, wherein the second metal pattern and the third metal pattern each include a same material.

17. The semiconductor package of claim 9, wherein the second metal pattern and the third metal pattern are integrated with each other.

18. A semiconductor package comprising:
a first redistribution structure comprising a plurality of first redistribution line patterns and a first redistribution insulation layer at least partially surrounding the plurality of first redistribution line patterns;
a connection structure disposed on the first redistribution structure in a first direction and comprising a metal pattern, a cavity, a plurality of connection pads, a plurality of connection vias, and a plurality of base layers at least partially surrounding the plurality of connection vias, wherein connection pads of the plurality of connection pads are disposed on different levels in the first direction from each other, and wherein the plurality of connection vias interconnect the plurality of connection pads;
a semiconductor chip disposed on the first redistribution structure in the first direction;
a molding layer disposed between the connection structure and the semiconductor chip and covering a top surface in the first direction of the connection structure and of the semiconductor chip, wherein the semiconductor chip and the molding layer are disposed in the cavity; and
a second redistribution structure disposed on the semiconductor chip in the first direction and comprising a plurality of second redistribution line patterns and a second redistribution insulation layer at least partially surrounding the plurality of second redistribution line patterns,
wherein the metal pattern is at least partially disposed between the plurality of base layers and the molding layer, the metal pattern comprising:
a first metal pattern extending, in a second direction crossing the first direction, from an inner surface of the connection structure into the plurality of base layers and separating at least a portion of the plurality of base layers from at least a portion of the first redistribution structure;
a second metal pattern disposed on an inner surface of the first metal pattern and extending in the first direction from a top surface in the first direction of the first redistribution structure to a top surface in the first direction of an uppermost base layer in the first direction of the plurality of base layers; and
a third metal pattern disposed on a top surface in the first direction of the second metal pattern and of the uppermost base layer and extending, in the second direction, from an inner surface of the second metal pattern toward the plurality of base layers.

19. The semiconductor package of claim 18, wherein the first metal pattern, the second metal pattern, the third metal pattern, and a connection pad of the plurality of connection pads each include a same material.

20. The semiconductor package of claim 18, wherein a base layer of the plurality of base layers comprises a prepreg material and the first redistribution insulation layer comprises a photoimageable dielectric (PID) material.
